(19) United States
(12) Patent Application Publication
(10) Pub. No.: US 2007/0018691 A1
(43) Pub. Date: Jan. 25, 2007

(54) Multi-pad structure for semiconductor device

(75) Inventors: Hyuk-Joon Kwon, Gyeonggi-do (KR); Sang-Woong Shin, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: Samsung Electronics Co., Ltd., Gyeonggi-Do, (KR)

(21) Appl. No.: 11/428,819

(22) Filed: Jul. 5, 2006

(30) Foreign Application Priority Data
Jul. 12, 2005 (KR) 2005-0062603

(51) Int. Cl. H03K 19/00

(52) U.S. Cl. 326/101

(57) ABSTRACT

A pad layout structure may include a pad and adjacent circuit areas having an electrostatic protection circuit and a data input/output circuit. The pad may be selectively connected to the adjacent circuit areas depending on the intended use of the pad.

### CROSS-REFERENCE TO RELATED APPLICATIONS

This application claims priority from Korean Patent Application 2005-62603, filed on Jul. 12, 2005, which is incorporated by reference.

### BACKGROUND

Advanced semiconductor technology is rapidly increasing memory capacity and processing speed. The development of metal oxide semiconductor (MOS) transistors, which have replaced bipolar transistors, has significantly advanced semiconductor technology.

Typically, pads allowing electrical connections from elements external to a chip forming a semiconductor device are laid out in peripheral areas of the chip. Addresses, commands, and signals associated with data read and write operation are input to the chip or output from the chip via the pads. The pads, which have connections to internal circuits of the chip, are connected to package pins through wire bonding.

Each pad has adjacent circuit areas located adjacent to the pad where the circuits to be directly connected to the pad are laid out. These circuits can be of any nature and type, for example, electrostatic protection circuits, data output driver circuits, and on-die termination (ODT) circuits. The intended usage of the pad determines what type of circuits are laid out in the adjacent circuit areas. The pad is then connected according to a packaging form required by the user.

FIGS. 1 to 5 illustrate prior art layout of pads in a conventional semiconductor device. Specifically, FIGS. 1 and 2 illustrate the layout of conventional input pads and FIGS. 3-5 illustrate the layout of conventional output pads.

As shown in FIG. 1, in a conventional semiconductor device, a pad 10 is first laid out, and an electrostatic protection circuit is laid out in pad adjacent circuit areas 12 and 14 which are located at opposite sides of the pad 10 in one direction, for example, the vertical direction in this case.

An electrostatic protection circuit generally includes clamp diodes or electrostatic discharge (ESD) diodes to prevent the occurrence of electrostatic discharge phenomenon.

The electrostatic discharge phenomenon refers to instantaneous discharge affecting elements in a chip when an electrically charged object comes in contact with a semiconductor device. A CMOS type semiconductor device, generally used as a memory device, is susceptible to such discharge and needs to be protected. If a high voltage exceeding the operating voltage range of the semiconductor device is applied to a pin of the device, conductive lines spaced at micron intervals may be short-circuited, a wiring layer and an oxide layer formed in thicknesses measured in angstroms (A) may be damaged, and unit elements at an input side may be damaged. These are mainly caused by static electricity flowing into pins of a semiconductor device. This is called “electrostatic breakdown” or “electrostatic discharge (ESD).”

The electrostatic protection circuit is divided into a P type clamp or ESD diode and an N type clamp or ESD diode. These are laid out at opposite sides of the pad 10.

The pad 10 is electrically connected to the electrostatic protection circuit 12 and 14 by metal lines 16 and 18 respectively. The usage of pad 10 depends on the type of circuits in the pad adjacent circuit areas. When the electrostatic protection circuit is laid out in the adjacent circuit area, the pad functions as an input pad. In this case, the electrostatic protection circuit is connected to input related circuits such as an internal address input buffer circuit or an internal command input buffer circuit, and an external address or command signal is input via the pad 10.

FIG. 2 illustrates another prior art input pad layout in a conventional semiconductor device. As shown in the figure, a pad 20 is first laid out, and an electrostatic protection circuit is laid out in adjacent circuit areas 22 and 24 which are located at opposite sides of the pad 20 in a direction (e.g. the horizontal direction) perpendicular to the direction of FIG. 1.

The electrostatic protection circuit is divided into a P type clamp or ESD diode and an N type clamp or ESD diode, which are laid in adjacent circuit areas 22 and 24 respectively.

The pad 20 is electrically connected to electrostatic devices laid out in adjacent circuit areas 22 and 24 via metal lines 26 and 28 respectively. The usage of pad 20 depends on the type of circuits in the pad adjacent circuit areas. When the electrostatic protection circuit is laid out in the pad adjacent circuit area, the pad functions as an input pad. In this case, the electrostatic protection circuit is connected to input related circuits such as an internal address input buffer circuit or an internal command input buffer circuit, and an external address or command signal is input via the pad 20.

FIGS. 3 to 5 illustrate examples of a pad layout structure where the pads are used as data input/output pads (DQ PADs) in a conventional semiconductor device.

As shown in FIG. 3, a rectangular pad 30 is laid out, and a data output driver and an on die termination (ODT) circuit are laid out in adjacent circuit areas 32, 34, 36 and 38 which are located adjacent to edges of the pad.

The ODT circuit is divided into a pull-down circuit and a pull-up circuit, which are laid out in the adjacent circuit areas 36 and 38 respectively, and are located adjacent to the opposite edges of the pad 30 in a first direction (e.g., horizontal direction). The data output driver circuit is divided into a pull-up driver circuit and a pull-down driver circuit, which are laid out in the adjacent circuit areas 32 and 34, which are located adjacent to the opposite edges of the pad 30 in a second direction (e.g., vertical direction) perpendicular to the first direction. However, the ODT circuit and the data output driver may have different alignments as well.

The pad 30 is connected to the pull-up driver circuit, the pull-down driver circuit, the pull-down ODT circuit, and the pull-up ODT circuit by metal lines 33, 35, 37, and 39 respectively and functions as a data input/output pad.

FIG. 4 illustrates a pad 40, and a data output driver circuit and an ODT circuit laid out in adjacent circuit areas 42 and 44 at left and right sides of the pad 40 while partially surrounding the top and the bottom sides of the pad 40.

A pull-up data output driver circuit and a pull-down ODT circuit are laid out together in the adjacent circuit area 42 at the left of the pad 40 and partially over and under the pad 40. A pull-down data output driver circuit and a pull-up ODT circuit are laid out together in the adjacent circuit area 44 located at the right of the pad 40 and partially over and under the pad 40, as shown in the figure.

The pad 40 is connected to the adjacent circuit areas 42 and 44 via metal lines 46 and 48 respectively, and functions as a data input/output pad.

FIG. 5 illustrates a pad 50, and a data output driver circuit and an ODT circuit laid out in adjacent circuit areas 52 and 54 over and under the pad 40 while partially surrounding the left and right side of the pad 50.

A pull-up data output driver circuit and a pull-down ODT circuit are laid out together in the adjacent circuit area 52 located over the pad 50, including portions at the left and right sides of the pad 50. A pull-down data output driver circuit and a pull-up ODT circuit are laid out together in the adjacent circuit area 54 located under the pad 50, including portions at the left and right sides of the pad 50.

The pad 50 is connected to the adjacent circuit areas 52 and 54 via metal lines 56 and 58 respectively, and functions as a data input/output pad.

When the electrostatic protection circuit such as a clamp diode or ESD diode is laid out in a pad adjacent circuit area, the pad is used as an input pad, and when the data output driver circuit or the ODT circuit is laid out in the pad adjacent circuit area, the pad is used as a data input/output pad. In other words, when the pad is an input pad for inputting an address signal or a command signal, only input related circuits such as an electrostatic protection circuit are laid out in the pad adjacent circuit area, and when the pad is a data input/output pad, only data input/output related circuits such as an output driver circuit is laid out in the pad adjacent circuit area. The pad is electrically connected to the circuits in the pad adjacent circuit area via metal lines and then a packaging process is performed according to the usage of the pad.

However, a conventional pad layout structure as described above has the following drawbacks. Different pad layouts may be required for different packaging forms for the same semiconductor device. For example, some users may require a thin small outline package (TSOP) form, while other users require a thin quad flat package (TQFP) form, a flexible (PCB or tape) ball grid array (FBGA) form, or any other suitable form. However, different packaging forms may require different that the pads have different placement dimensions, and/or positions of input or output pads. For example, in the TSOP form, a pad connected to a second pin of a chip may be used as a data input/output pad. However, in the TQFP or FBGA form the pad may be used as an address or command pad, and not the data input/output pad. Thus a change in packaging form requires a new chip design. Furthermore, the packaging form needs to be determined first in order to determine each pad layout structure, and a change in the packaging form necessitates a change in pad design and associated manufacturing processes.

### SUMMARY

Some of the inventive principles of this patent disclosure relate to a pad layout structure having a pad, and adjacent circuit areas adjacent to the pad, wherein an electrostatic protection circuit and a data input/output circuit are arranged in the adjacent circuit areas.

In one embodiment, a multi-pad structure includes a pad and adjacent circuit areas located adjacent to the edges of the pad, wherein an electrostatic protection circuit for inputting an address signal or a command signal, and a data input/output circuit for inputting/outputting data are laid out together in the adjacent circuit area. The data input/output circuit may include a data output driver circuit. The electrostatic protection circuit may include ESD diodes or clamp diodes.

The pad may be laid out in a rectangular form. The data output driver circuit may be divided into a pull-up driver and a pull-down driver, the pull-up driver and the pull-down driver being respectively laid out in any two adjacent circuit areas among the four adjacent circuit areas located adjacent to four edges of the pad. The ESD diodes or clamp diodes may be divided into a P type diode and an N type diode, the P type diode and the N type diode being laid out in two other adjacent circuit areas in which the data output driver circuit is not laid out.

When the pad is a data pad, a conductive line may be further laid out for electrically connecting the data output driver circuit laid out in the adjacent circuit area and the pad. When the pad is an input pad for inputting an address or command, a conductive line may be laid out for electrically connecting the electrostatic protection circuit laid out in the adjacent circuit area and the pad. When the pad is a power pad, a conductive line may be laid out which electrically connects to a power line laid out around the adjacent circuit area without having an electrical connection to the electrostatic protection circuit or the data output driver circuit. When the pad is a monitor pad, a conductive line may be further laid out for electrically connecting a signal transfer line extending from a monitor circuit outside the pad to the adjacent circuit area and the pad.

Some additional inventive principles of this patent disclosure relate to a semiconductor device having a plurality of pads spaced apart, and adjacent circuit areas, wherein adjacent circuit areas adjacent to any individual pad includes both an electrostatic protection circuit and a data input/output circuit.

In one embodiment, a semiconductor device includes a multi-pad structure with multi-usage, the device comprising: a plurality of pads having a spacing therebetween; and adjacent circuit areas located adjacent to the plurality of pads and including circuits for directly connecting to the pads, wherein the adjacent circuit area adjacent to individual pad includes both an electrostatic protection circuit for inputting an address signal or a command signal and a data input/output circuit for inputting and outputting data. The electrostatic protection circuit may include ESD diodes or clamp diodes. The data input/output circuit may include a data output driver circuit.

A first pad of the pads may be used as a data input/output pad by electrically connecting to a data output driver circuit in an adjacent circuit area located adjacent to the first pad. A second pad may be used as an input pad for inputting an address or a command by electrically connecting to an electrostatic protection circuit in an adjacent circuit area located adjacent to the second pad. A third pad may be used as a power pad by electrically connecting to a power line around an adjacent circuit area located adjacent to the third pad with no electrical connection to an electrostatic protection circuit or a data output driver circuit in the adjacent circuit area located adjacent to the third pad. A fourth pad may be used as a monitor pad by electrically connecting a signal transfer line extending from a monitor circuit outside the fourth pad to an adjacent circuit area located adjacent to the fourth pad and the fourth pad.

Some additional inventive principles of this patent disclosure relate to a method including forming a pad, forming an electrostatic protection circuit and a data input/output circuit in adjacent circuit areas adjacent to the pad, and forming a conductive line connected to the pad depending on the usage of the pad.

### BRIEF DESCRIPTION OF THE DRAWINGS

FIGS. 1 and 2 illustrate the layout of a prior art input pad;

FIGS. 3 to 5 illustrate the layout of a prior art output pad;

FIGS. 6 to 9 illustrate several exemplary embodiments of a layout of a multi-pad according to the inventive principles of this patent disclosure; and

FIGS. 10 to 13 illustrate several exemplary embodiments of layout of connections between adjacent circuits and a pad of FIG. 6 according to the inventive principles of this patent disclosure.

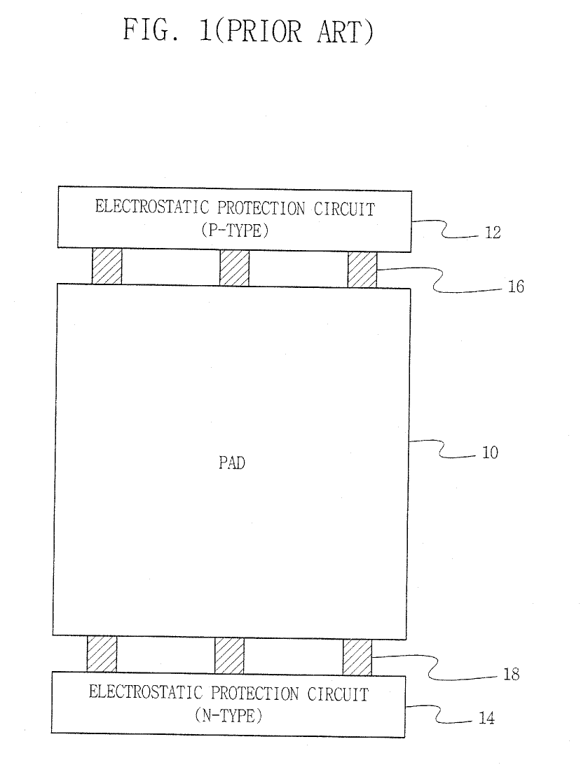

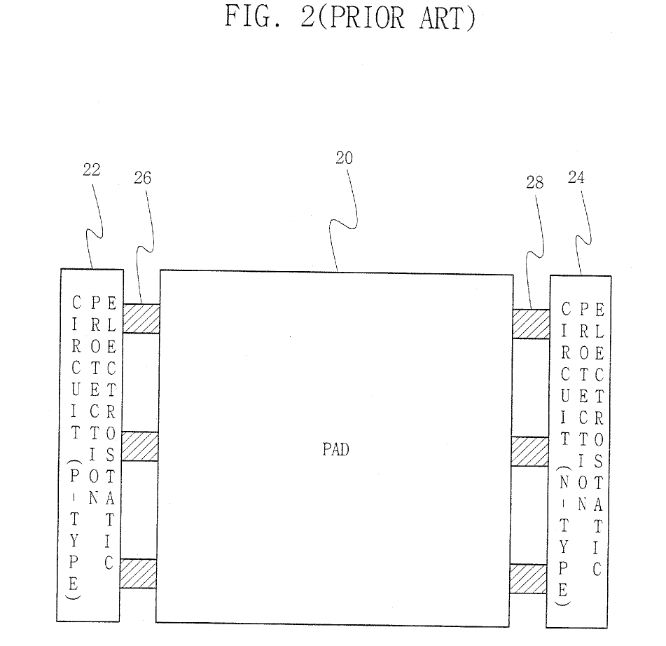

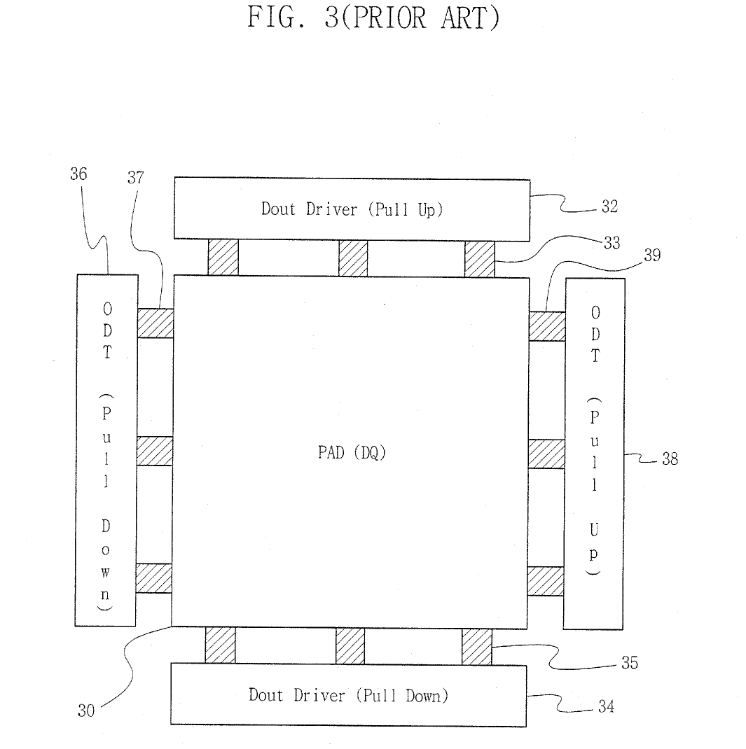

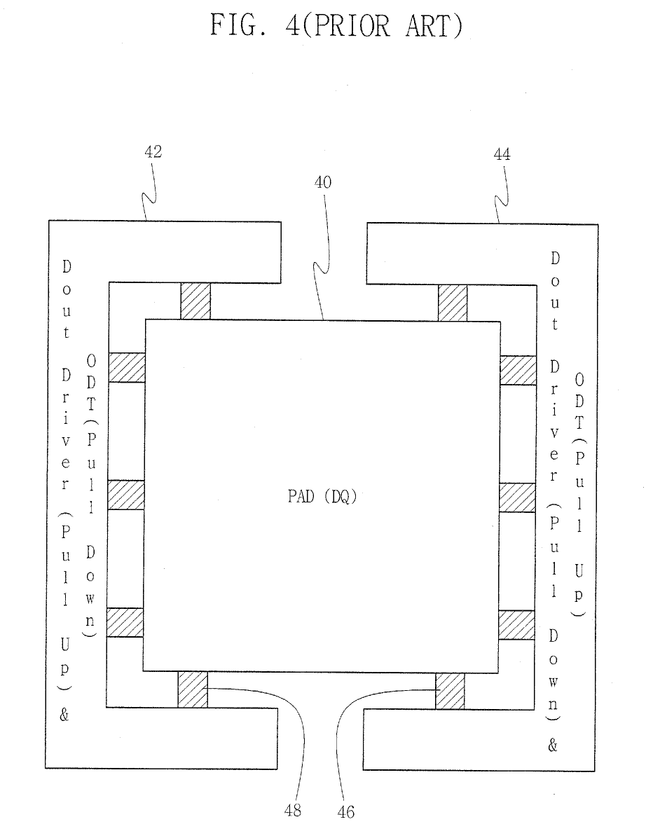

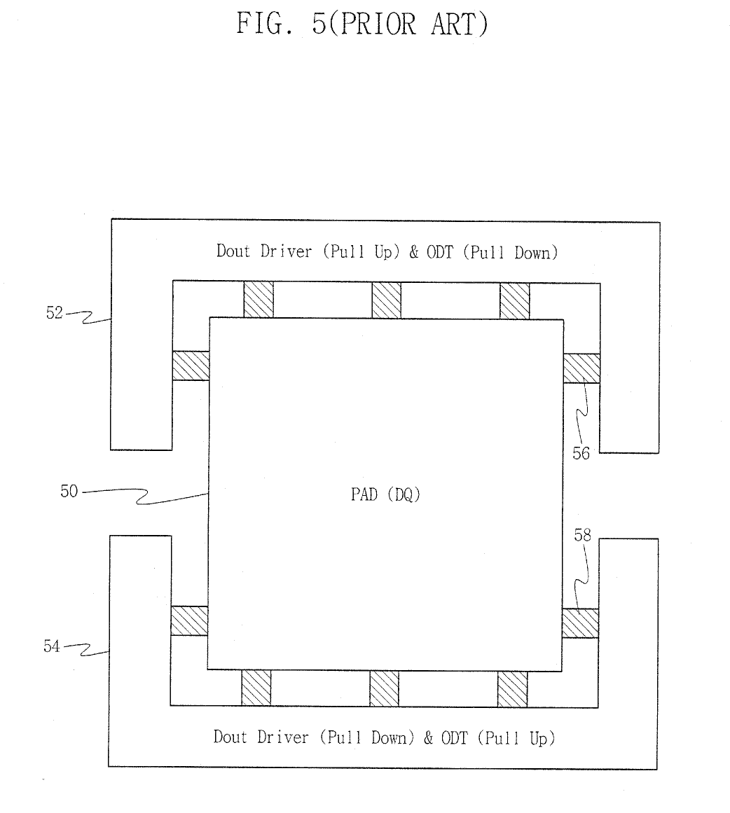

### DETAILED DESCRIPTION

The inventive principles of this patent disclosure will be described with reference to the accompanying drawings, in which preferred embodiments are shown. These inventive principles may, however, be embodied in many different forms and should not be construed as being limited to the embodiments set forth herein. Rather, these embodiments are provided so that this disclosure will be thorough and complete, and will fully convey the scope of the inventive principles to those skilled in the art. While a form of a pad according to embodiments of the present invention may include a variety of forms such as a polygonal form and a circular form, it is hereinafter assumed that the pad is in a rectangular form that is a typical form for purposes of illustration. Further, the size, form, and layout of the pad may change according to the type of semiconductor device. Typically, pads are laid out with a certain pitch and a spacing therebetween, since peripheral circuit areas need to be laid out. While a layout structure of one pad has been shown in the following figures, it is common that several pads, tens of pads, or even hundreds of pads are laid out in a semiconductor device. A greater number of pads may be laid out, if necessary. When a plurality of pads are laid out, they may be laid out with a certain pitch and spacing therebetween and some of them may be laid out with different spacing.

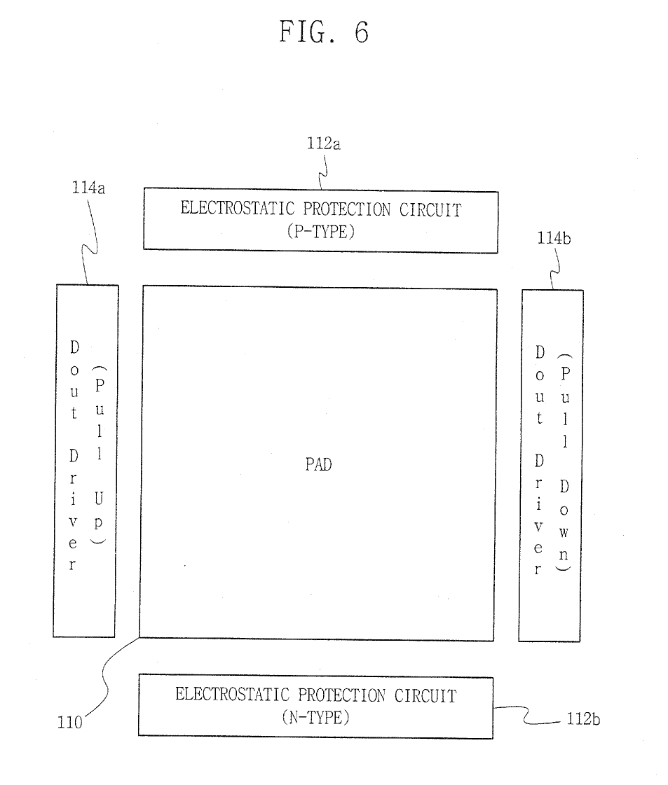

FIGS. 6 to 9 illustrate exemplary layout structures of embodiments of multi-pads in a semiconductor device according to the inventive principles of this patent disclosure.

As shown in FIGS. 6 to 9, a pad layout structure includes a pad and adjacent circuit areas in which circuits directly connected to the pad are laid out. The circuits may include an electrostatic protection circuit for inputting an address signal, a command signal and the like; and a data input/output circuit for inputting/outputting data. That is, an electrostatic protection circuit for connecting to an input pad, and a data output driver circuit (Dout Driver) for connecting to a data input/output pad may be laid out together in the pad adjacent circuit area, unlike a conventional pad layout. The usage of the pad is determined based on the type of circuit connected to the pad.

As shown in FIG. 6, a pad 110, and pad adjacent circuit areas 112a, 112b, 114a and 114b are laid out adjacent to the edges of the pad 110. A data output driver circuit is divided into a pull-up driver circuit and a pull-down driver circuit which are laid out in the adjacent circuit areas 114a and 114b respectively, adjacent to the opposite edges of the pad 110 in a first direction (e.g., horizontal direction). For example, the pull-up driver circuit may be laid out in the left adjacent circuit area 114a of the pad 110, and the pull-down driver circuit may be laid out in the right adjacent circuit area 114b of the pad 110.

An electrostatic protection circuit is laid out in the adjacent circuit areas 112a and 112b adjacent to the opposite edges of the pad 110 in a second direction (e.g., vertical direction) perpendicular to the first direction. When the electrostatic protection circuit is composed of an ESD diode or a clamp diode, it is divided into a P type diode and an N type diode, in which the P type diode may be laid out in the adjacent circuit area 112a over the pad 110, and the N type diode may be laid out in the adjacent circuit area 112b under the pad 110. However, it should be understood that the inventive principles of this patent disclosure are not limited to this particular orientation of pad layout and other different layouts may also be possible.

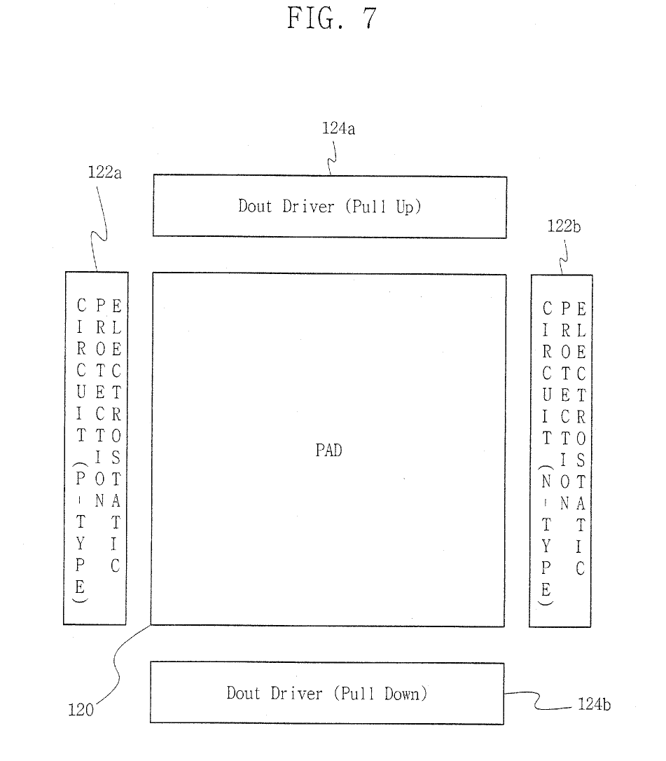

As shown in FIG. 7, a pad 120, and pad adjacent circuit areas 122a, 122b, 124a and 124b are laid out adjacent to edges of the pad 110. An electrostatic protection circuit is laid out in the adjacent circuit areas 122a and 122b facing the pad 120 in the first direction (e.g., horizontal direction). When the electrostatic protection circuit is composed of an ESD diode or a clamp diode, it is divided into a P type diode and an N type diode, in which the P type diode may be laid out in the adjacent circuit area 122a at the left of the pad 110, and the N type diode maybe laid out in the adjacent circuit area 122b at the right of the pad 110.

A data output driver circuit that is divided into a pull-up driver circuit and a pull-down driver circuit maybe laid out in the adjacent circuit areas 124a and 124b respectively facing the pad 120 in the second direction (e.g., vertical direction). That is, the pull-up driver circuit maybe laid out in the adjacent circuit area 124a over the pad 120, and the pull-down driver circuit maybe laid out in the adjacent circuit area 124b under the pad 120.

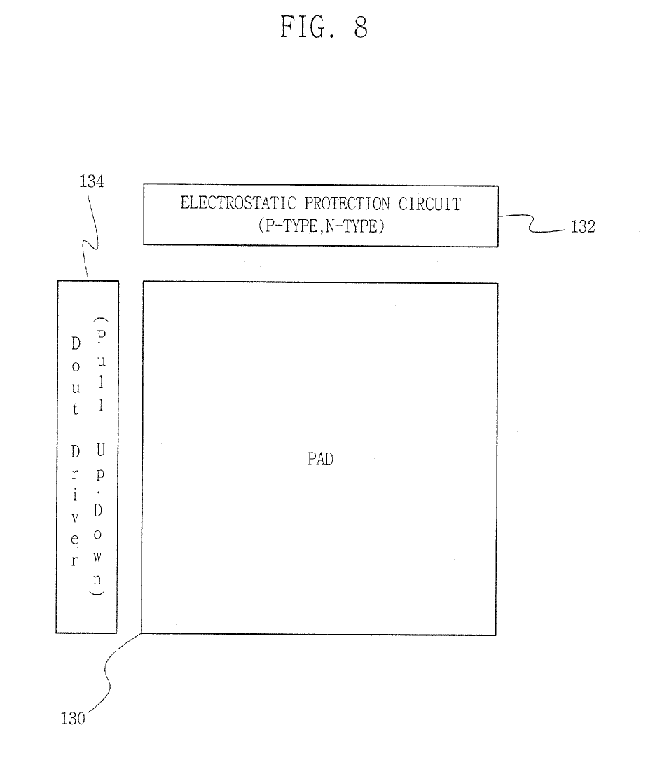

As shown in FIG. 8, a pad 130, and adjacent circuit areas 132 and 134 are laid out adjacent to some edges of the pad 130. An electrostatic protection circuit is laid out in the adjacent circuit area 132 adjacent to one edge of the pad 130 (e.g., over the pad 130). In this example, both the P type diode and an N type diode are laid out in the same area. A pull-up driver circuit and a pull-down driver circuit and are laid out in the same adjacent circuit area 134 located adjacent to another edge of the pad 130 (e.g., at the left of the pad 130). However, the electrostatic protection circuit and the data output driver circuit may be laid out in different orientation as well, for example, at bottom and right; or on opposite edges of the pad.

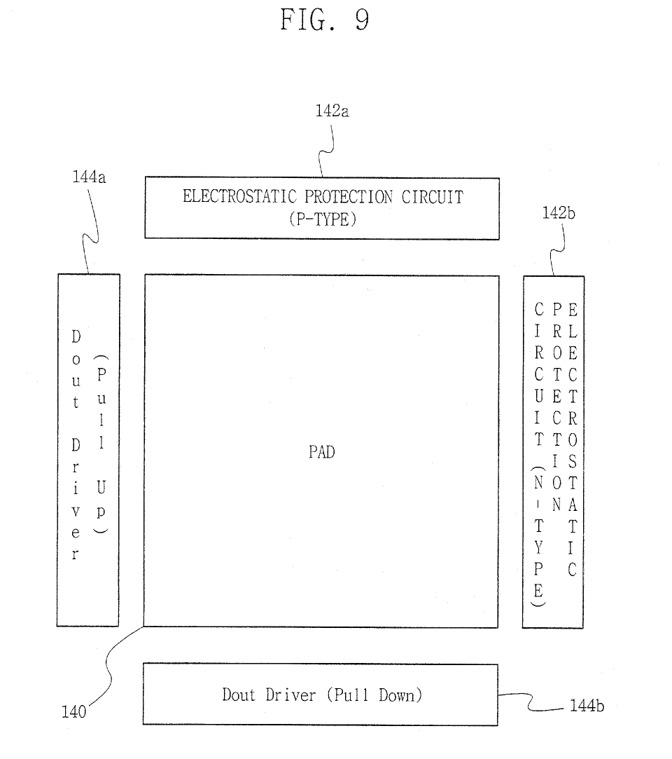

As shown in FIG. 9, a pad 140, and adjacent circuit areas 142a, 142b, 144a and 144b are laid out adjacent to edges of the pad 140. An electrostatic protection circuit is laid out in the adjacent circuit areas 142a and 142b located along adjacent edges (for example, above and to the right). When the electrostatic protection circuit is composed of an ESD diode or a clamp diode, the electrostatic protection circuit are divided into a P type diode and an N type diode, in which the P type diode may be laid out in the adjacent circuit area 142a over the pad 140, and the N type diode maybe laid out in the adjacent circuit area 142b at the right of the pad 140.

A data output driver circuit may be divided into a pull-up driver circuit and a pull-down driver circuit that are laid out in the other adjacent circuit areas 144a and 144b respectively. For example, the pull-up driver circuit may be laid out in the adjacent circuit area 144a at the left of the pad 140, and the pull-down driver circuit may be laid out in the adjacent circuit area 144b under the pad 140.

In some of the exemplary embodiments of the pad layout structures described above (FIGS. 6, 7 and 9), the data output driver circuit for inputting and outputting data is divided into a pull-up driver circuit and a pull-down driver circuit, and these are laid out in any two adjacent circuit areas. Further, the electrostatic protection circuit for inputting an address signal or a command signal is divided into a P type circuit and an N type circuit and these are laid out in two other adjacent circuit areas. In another exemplary embodiment of the pad layout structure (FIG. 8), the data output driver circuit and the electrostatic protection circuit may be laid out in two adjacent circuit areas.

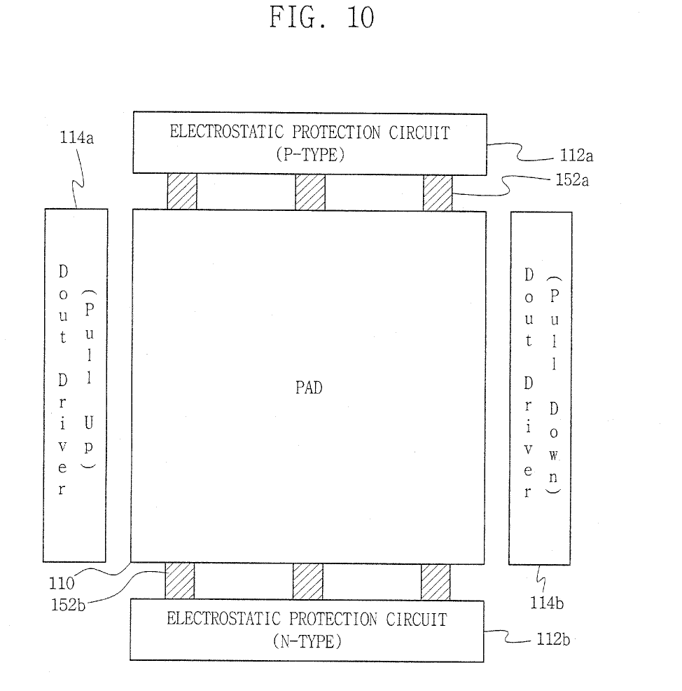

FIGS. 10 to 13 illustrate exemplary embodiments of layout structures according to the inventive principles of this patent disclosure where connections between adjacent circuits and a pad as shown in FIG. 6 are arranged according to the intended usage of the pad. While FIGS. 10 to 13 show a connection layout structure only for the pad of FIG. 6, connection layout structures for pads of FIGS. 7 to 9 can be easily inferred by those skilled in the art and thus illustration and description thereof will be omitted.

As shown in FIG. 10, when a pad 110 is used as an input pad (second pad), metal lines 152a and 152b are laid out for electrically connecting the pad 110 and an electrostatic protection circuit in adjacent circuit areas 112a and 112b. That is, the metal line 152a is laid out to electrically connect the pad 110 and a P type diode in the adjacent circuit area 112a over the pad 110, and the metal line 152b is laid out to electrically connect the pad 110 and an N type diode in the adjacent circuit area 112b under the pad. In this case, the P type diode and the N type diode function as one electrostatic protection circuit by electrically connecting to each other via the pad 110. The electrostatic protection circuit may be connected to an address input buffer circuit or a command input buffer circuit in the semiconductor device. Such a layout structure allows the pad 110 to function as an input pad for inputting an address signal, a command signal, or the like.

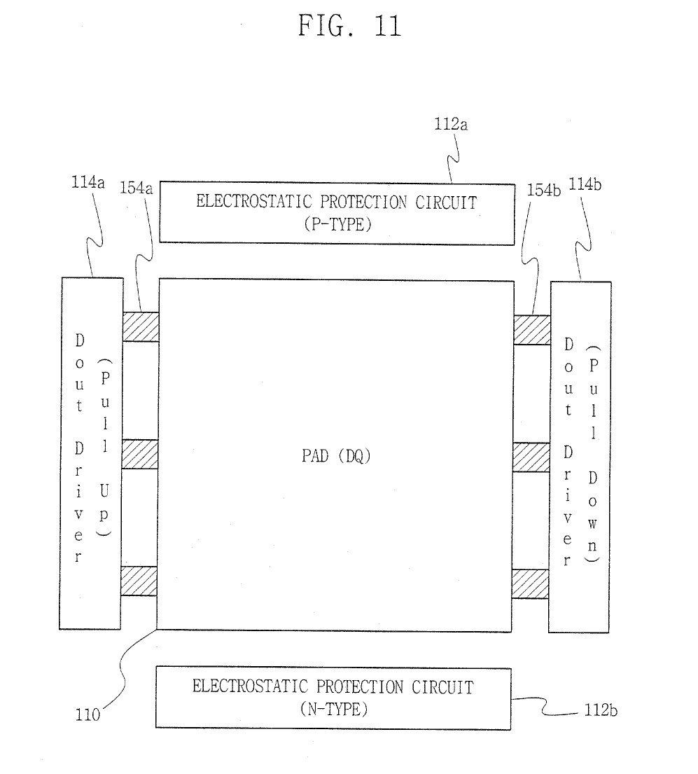

As shown in FIG. 11, when the pad 110 is used as a data input/output pad (first pad), metal lines 154a and 154b are laid out to electrically connect the pad 110 and a data output driver circuit in adjacent circuit areas 114a and 114b. That is, the metal line 154a is laid out to electrically connect the pad 110 and a pull-up driver circuit in the adjacent circuit area 114a at the left of the pad 110, and the metal line 154b is laid out to electrically connect the pad 110 and a pull-down driver circuit in the adjacent circuit area 114b at the right of the pad 110. In this case, a data input buffer in the semiconductor device may be additionally connected to the pad 110. Further, the pull-up driver circuit and the pull-down driver circuit function as one output driver by electrically connecting to each other via the pad 110. Such a layout structure allows the pad 110 to function as a data input/output pad DQ for inputting and outputting data.

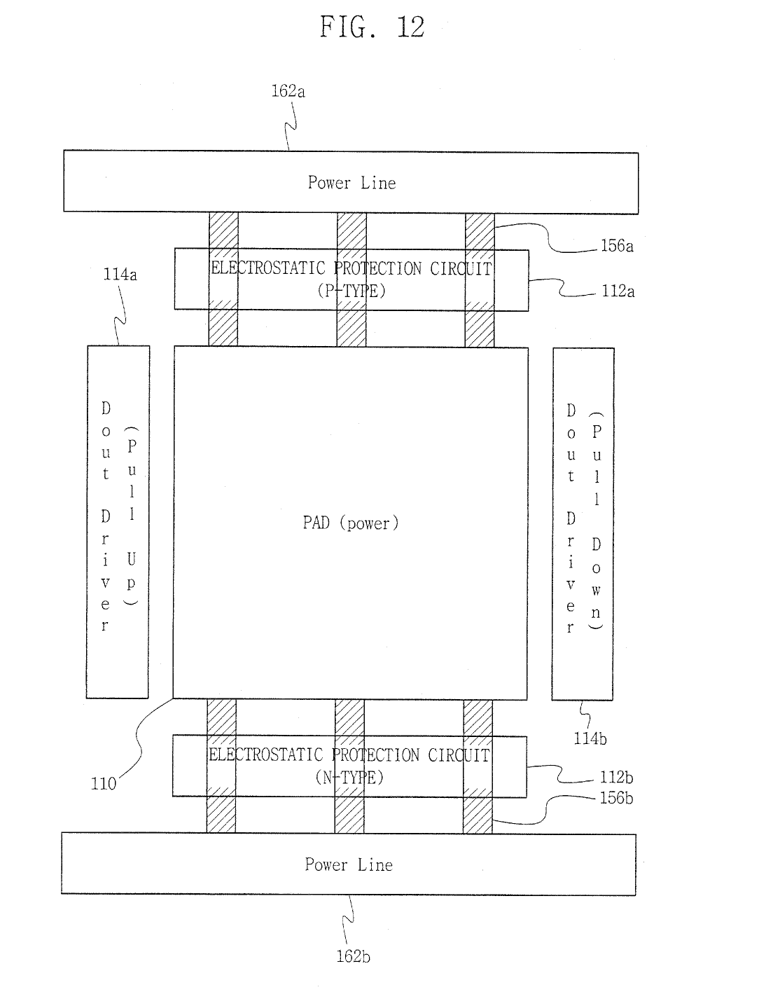

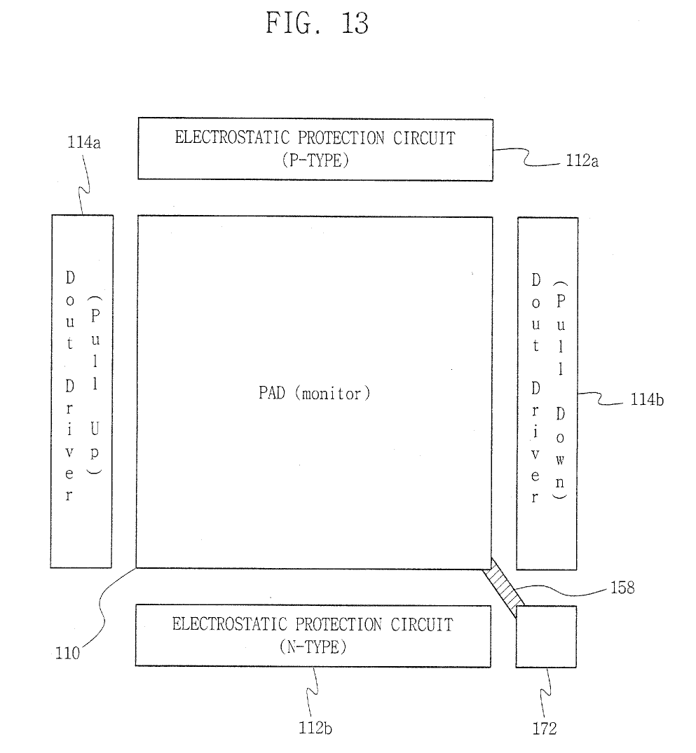

FIGS. 12 and 13 illustrate cases in which metal lines are not laid out to electrically connecting the pad 110 and the circuits in the adjacent circuit areas 112a, 112b, 114a, and 114b.

As shown in FIG. 12, when the pad 110 is used as a power pad (third pad), it is not electrically connected to the output driver circuit or the electrostatic protection circuit in the adjacent circuit areas 112a, 112b, 114a and 114b. Instead, metal lines 156a and 156b are laid out to provide connections to power lines 162a and 162b, which are laid out around the circuits in the adjacent circuit areas 112a, 112b, 114a, and 114b. The power lines 162a and 162b are laid out on another layer that is electrically isolated from the output driver circuit or the electrostatic protection circuit. In this manner, the metal lines 156a and 156b can be laid out for electrically connecting the power lines 162a and 162b and the pad 110 with no electrical connection to the output driver circuit or the electrostatic protection circuit.

As shown in FIG. 13, when the pad 10 is used as a monitor pad (fourth pad), it is not electrically connected to the output driver circuit or the electrostatic protection circuit in the adjacent circuit areas 112a, 112b, 114a and 114b. A metal line 158 is laid out for connecting the pad to a signal transfer line 172 extending from a monitor circuit (not shown) which is laid out around the circuits in the adjacent circuit areas 112a, 112b, 114a and 114b. The signal transfer line 172 is shown as a box instead of a line for convenience of illustration.

In this case, the monitor pad allows information about process variation to be easily recognized through a comparison with an actually measured value on a semiconductor device (chip) fabricated through an actual process using test equipment. Examples of the monitor pad include a bit line voltage related pad for verifying sensing operation, and a pad for monitoring a level of an internal voltage in an element that uses the internal voltage.

As described above, with the layout structure of a multi-pad and the semiconductor device according to the inventive principles of this patent disclosure, the same process may be used irrespective of packaging forms, and the pad may be electrically connected to any one of the data output driver circuit, the electrostatic protection circuit, the power line, and the monitor signal transfer line according to usage of the pad immediately before packaging. For example, if a pad located at a specific position needs to be a data output pad for packaging into a TSOP form, the pad may be connected to the output driver circuit and used as a data output pad. On the other hand, if the pad needs to be an address signal input pad for packaging into a TQFP form, the pad may be connected to the electrostatic protection circuit for the address signal input pad. Thus, pads derived from the same process can be used for different purposes. The same structure of the pad may be easily applied without a process or design modification for different packaging forms, and a multi-pad having a variety of usages can be implemented.

The inventive principles have been described using preferred exemplary embodiments. As described above, according to the inventive principles of this patent disclosure, packaging can be easily performed in a variety of forms without a process or design burden for different packaging forms. In addition, a multi-pad can be implemented with a variety of usage. However, it is to be understood that the scope of the inventive principles are not limited to the disclosed embodiments. On the contrary, the scope is intended to include various modifications and alternative arrangements within the capabilities of persons skilled in the art using presently known or future technologies and equivalents. The scope of the claims, therefore, should be accorded the broadest interpretation so as to encompass all such modifications and similar arrangements. For example, various variations and modifications may be made to the form or position of the pad, the positions or forms of the adjacent circuit areas located adjacent to the pad, and the like.

Since the embodiments described herein may be modified in arrangement and detail without departing from the inventive principles, such changes and modifications are considered to fall within the scope of the following claims.

1. A pad layout structure comprising:
a pad; and
adjacent circuit areas adjacent to the pad;
wherein an electrostatic protection circuit and a data input/output circuit are arranged in the adjacent circuit areas.

2. The structure according to claim 1, wherein the data input/output circuit comprises a data output driver circuit.

3. The structure according to claim 2, wherein the data output driver circuit is divided into a pull-up driver and a pull-down driver, the pull-up driver and the pull-down driver being laid out in any two adjacent circuit areas.

4. The structure according to claim 1, wherein the electrostatic protection circuit comprises ESD diodes or clamp diodes.

5. The structure according to claim 4, wherein the ESD diodes or clamp diodes are divided into a P type diode and an N type diode, the P type diode and the N type diode being laid out in any two adjacent circuit areas.

6. The structure according to claim 5, wherein the data output driver circuit is divided into a pull-up driver and a pull-down driver, the pull-up driver and the pull-down driver being laid out in any two adjacent circuit areas in which the electrostatic protection circuit is not laid out.

7. The structure according to claim 1, further comprising one or more conductive lines coupled to the pad.

8. The structure according to claim 7, wherein the conductive lines couple the pad to the data output driver circuit.

9. The structure according to claim 7, wherein the conductive lines couple the pad to the electrostatic protection circuit.

10. The structure according to claim 7, wherein the conductive lines couple the pad to a power line laid out around the adjacent circuit area without having an electrical connection to the electrostatic protection circuit or the data output driver circuit.

11. The structure according to claim 7, wherein the conductive lines couple the pad to a signal transfer line extending from a monitor circuit.

12. A semiconductor device comprising:
a plurality of pads spaced apart; and
adjacent circuit areas;
wherein adjacent circuit areas adjacent to any individual pad includes both an electrostatic protection circuit and a data input/output circuit.

13. The device according to claim 12, wherein the data input/output circuit comprises a data output driver circuit.

14. The device according to claim 13, wherein a first one of the pads is electrically connected to a data output driver circuit in an adjacent circuit area located adjacent to the first pad.

15. The device according to claim 14, wherein the first pad is electrically connected to a data input buffer outside the adjacent circuit area located adjacent to the first pad.

16. The device according to claim 14, wherein a second one of the pads is electrically connected to an electrostatic protection circuit in an adjacent circuit area located adjacent to the second pad.

17. The device according to claim 16, wherein a third one of the pads is electrically connected to a power line around an adjacent circuit area located adjacent to the third pad with no electrical connection to an electrostatic protection circuit or a data output driver circuit in the adjacent circuit area located adjacent to the third pad.

18. The device according to claim 17, wherein a fourth pad is electrically connected to a signal transfer line extending from a monitor circuit.

19. A method comprising:
forming a pad; and
forming an electrostatic protection circuit and a data input/output circuit in adjacent circuit areas adjacent to the pad.

20. The method of claim 19 further comprising forming a conductive line connected to the pad depending on the usage of the pad.

21. The method of claim 20, wherein forming a conductive line comprises connecting the pad to the electrostatic protection circuit.

22. The method of claim 20, wherein forming a conductive line comprises connecting the pad to the data input/output circuit.

23. The method of claim 20, wherein forming a conductive line comprises connecting the pad to a power line and not to the electrostatic protection circuit or the data output driver.

24. The method of claim 20, wherein forming a conductive line comprises connecting the pad to a monitor circuit.
